(19) United States
(12) Patent Application Publication
(10) Pub. No.: US 2001/0037939 A1
(43) Pub. Date: Nov. 8, 2001

(54) IMPURITY INTRODUCING APPARATUS AND METHOD

(75) Inventors: HIROAKI NAKAOKA, OSAKA (JP); BUNJI MIZUNO, NARA (JP); MICHIHIKO TAKASE, OSAKA (JP); ICHIROU NAKAYAMA, OSAKA (JP)

Correspondence Address: MCDERMOTT WILL & EMERY, 600 13TH STREET, N.W., WASHINGTON, DC, 20005-3096, US

(73) Assignee: Hiroaki Nakaoka

(21) Appl. No.: 08/693,749

(22) Filed: Aug. 7, 1996

(30) Foreign Application Priority Data
Aug. 10, 1995 (JP) 7-204253

(51) Int. Cl. C23C 14/34

(52) U.S. Cl. 204/192.15; 204/192.25; 204/298.05; 204/298.08; 204/298.25; 438/513; 438/519

(57) ABSTRACT

A sample table for holding a silicon substrate into which an impurity is introduced is provided in the lower portion of a vacuum chamber. A high frequency power source is connected to the sample table through a coupling capacitor. The high frequency power source has a self-bias of 500 V, for example. Gas introducing means for introducing a sputtering gas such as an argon gas is provided on the bottom of the vacuum chamber. A solid target which contains an impurity which should be introduced, for example, boron is provided in the upper portion of the vacuum chamber.

### BACKGROUND OF THE INVENTION

The present invention relates to an impurity introducing apparatus and method for introducing an impurity into a sample such as a silicon substrate or the like.

Recently, it has been necessary to reduce the junction depth of a diffusion layer of a transistor in order to prevent short channel effects and increase the speed of a device with a reduction in design rule of a semiconductor device. For this reason, a device having a 0.1 μm rule requires a junction depth of 80 nm or less in a MOSFET. Also in a bipolar transistor, the diffusion layer of a base region having a depth of 50 nm or less has been required to increase the speed. Thus, impurity introducing technique has been investigated in order to obtain shallower junction.

On the other hand, an ion implanting method has been known as the impurity introducing technique according to the prior art in which a gas comprising an impurity to be introduced is supplied into a vacuum chamber, the supplied impurity gas is excited and brought into the ionic state, and impurity ions are accelerated and implanted into the surface portion of a sample such as a silicon substrate.

However, the acceleration energy of the impurity ions should be reduced in order to obtain the shallow junction (for example, 30 nm or less) by an impurity introducing method in which the impurity gas introduced into the chamber is ionized, and the ionized impurity is accelerated and implanted into a silicon substrate as described above.

If the acceleration energy is reduced, an ion current is lowered so that the time for implantation is increased. Consequently, throughput becomes poor. In a mass-produced apparatus, if the acceleration energy is reduced more, the ion current cannot be obtained so that ion implantation itself cannot be performed.

Since the impurity ion having a high energy of about several keV is implanted by the ion implanting method according to the prior art, Rp (a projection range : an average depth, from the surface, of the impurity ion implanted during ion implantation) reaches the inside of the sample such as a silicon substrate. Consequently, it is impossible to obtain shallow junction in which the surface portion of the silicon substrate or the like has an impurity concentration of 1×10²⁰ (/cm³) or more.

In general, poisonous gases such as arsine, diborane and phosphine are used as material gases of the impurity for ion implantation. For this reason, it is necessary to utilize very expensive equipment in order to perform impurity introducing work with safety. Consequently, the apparatus cost becomes vast. Examples of the expensive equipment are a piping and a valve of high quality, through which the poisonous gases flow, a sensor for the poisonous gases, processing equipment for the poisonous gases, and the like.

### SUMMARY OF THE INVENTION

In consideration of the foregoing, it is an object of the present invention to introduce an impurity having a high concentration into a shallow position on the surface portion of a sample such as a silicon substrate and to perform impurity introducing work with safety.

In order to accomplish the above-mentioned object of the present invention, a gas for sputtering is caused to collide with a solid target containing an impurity in the plasma state so that the impurity flies out of the target and is introduced into the surface portion of the sample.

The present invention provides a first impurity introducing apparatus for introducing an impurity into a sample such as a semiconductor substrate or the like, comprising a vacuum chamber having an inside thereof kept in the vacuum state, a sample table which is provided in the vacuum chamber and holds the sample, a solid target which is provided in the chamber and contains the impurity, gas introducing means for introducing a gas for sputtering into the chamber, plasma generating means for exciting the gas introduced into the chamber to generate a plasma of the gas so that the gas which is in the plasma state is caused to collide with the target to sputter the impurity contained in the target, and a high frequency power source for forming a self-bias between the plasma generated by the plasma generating means and the sample table to introduce the sputtered impurity from the target into the surface portion of the sample held on the sample table.

According to the first impurity introducing apparatus, when the gas which is introduced into the chamber and excited to be brought into the plasma state is caused to collide with the target which contains the impurity, the impurity contained in the target is sputtered. If the self-bias is formed between the plasma and the sample table by the high frequency power source, the sputtered impurity is introduced from the target into the surface portion of the sample held on the sample table.

As described above, the plasma is caused to collide with the solid target which contains the impurity so that the impurity is sputtered. Therefore, the impurity can be introduced without using poisonous gases as in an ion implanting method. For this reason, impurity introducing work can be performed with safety. Consequently, it is not necessary to utilize expensive equipment such as a piping and a valve of high quality, a sensor for the poisonous gases, processing equipment for the poisonous gases. and the like. Thus, the size of the apparatus can be reduced and the apparatus cost can be lowered.

A low voltage of about several tens V to 2 kV is applied to the sample table so that the impurity is introduced with low energy. Consequently, the impurity is introduced intensively into the surface portion of the sample. As a result, the impurity having a high concentration can be introduced into a shallow region on the surface portion of the sample. For this reason, it is possible to realize very shallow junction having a depth of 30 nm or less. Consequently, it is possible to prevent short channel effects and to increase the speed of a device in a MOSFET having a fine design rule. In a bipolar transistor, furthermore, the depth of the diffusion layer in a base region can be reduced so that the speed of the device can be increased.

Even though the sample is kept at a low temperature, for example, of 23 to 160° C. unlike the ion implanting method, the impurity can be introduced. Consequently, impurity introducing processing can be performed by using an ordinary resist.

In the first impurity introducing apparatus, it is preferable that the plasma generating means should be provided on the outside of the vacuum chamber and introduce plasma waves having a frequency of 1 GHz or more into the vacuum chamber.

As a result, the plasma having a high density can be generated in the vacuum chamber. Consequently, the impurity having a predetermined concentration can be introduced into the surface portion of the semiconductor substrate in a short time. For this reason, it is possible to prevent such a rise in the temperature of the semiconductor substrate that a resist pattern burns. Thus, the impurity can surely be introduced into a predetermined region on the semiconductor substrate.

It is preferable that the first impurity introducing apparatus should further comprise magnetic field generating means for generating a magnetic field which raises the density of the plasma generated in the vacuum chamber. As a result, the ionization efficiency of the introduced gas is enhanced so that the plasma density is increased still more by the cooperation with the plasma generating means for introducing the plasma waves having a frequency of 1 GHz or more into the vacuum chamber. Consequently, the impurity having a predetermined concentration can be introduced into the surface portion of the semiconductor substrate in a much shorter time.

In the first impurity introducing apparatus, it is preferable that the target should contain boron and nitrogen as the impurity.

In a dual gate CMOS transistor in which an N channel transistor and a P channel transistor have different conductivity types of gates, it is necessary to prevent boron from penetrating from a gate electrode into a substrate so as not to adversely influence device characteristics. The introduction of nitrogen into a gate insulating film has been proposed so as to prevent the boron from penetrating from the gate electrode into the substrate. In order to introduce the nitrogen into the gate insulating film by the ion implanting method, it is necessary to introduce a nitrogen gas into a vacuum chamber and to accelerate nitrogen ions to be implanted into the gate electrode. According to this method, a step of implanting the nitrogen ions is required before or after the ion implanting step for forming an impurity layer which makes up a transistor.

On the other hand, if the target contains boron and nitrogen as the impurity, the boron and the nitrogen contained in the target are sputtered when the gas which is in the plasma state is caused to collide with the target. Consequently, the boron is introduced into the n type semiconductor region and gate electrode of the semiconductor substrate so that a p type source-drain region and a p type gate electrode are formed, and nitrogen atoms are introduced into the gate insulating film. The nitrogen atoms introduced into the gate insulating film prevent the boron introduced into the p type gate electrode from penetrating into a channel region of the n type semiconductor region at the heat treating step which will be executed later on. Thus, the characteristics of the p type MOS transistor can be enhanced.

In the first impurity introducing apparatus, it is preferable that the target should contain boron nitride. As a result, when the plasma gas is caused to collide with the target, boron atoms and nitrogen atoms are sputtered in the target. Similarly to the case where the target contains boron and nitrogen as the impurity, the nitrogen atoms are introduced into the gate insulating film. Thus, it is possible to prevent the boron introduced into the p type gate electrode from penetrating into the channel region of the n type semiconductor region.

In the first impurity introducing apparatus, it is preferable that the gas introduced by the gas introducing means should include an argon gas and a nitrogen gas. As a result, the nitrogen atoms are introduced into the gate insulating film in the same manner as in the above-mentioned case. Consequently, it is possible to prevent the boron introduced into the p type gate electrode from penetrating into the channel region of the n type semiconductor region.

The present invention provides a second impurity introducing apparatus for introducing first and second impurities into a sample such as a semiconductor substrate, comprising a first vacuum chamber having an inside thereof kept in the vacuum state, a first sample table which is provided in the first vacuum chamber and holds the sample, a first solid target which is provided in the first chamber and contains the first impurity, first gas introducing means for introducing a gas for sputtering into the first chamber, first plasma generating means for exciting the gas introduced into the first chamber to generate a plasma of the gas so that the gas which is in the plasma state is caused to collide with the first target to sputter the first impurity contained in the first target, a first high frequency power source for forming a first self-bias between the plasma generated by the first plasma generating means and the first sample table to introduce the first sputtered impurity from the first target into the sample held on the first sample table, a second vacuum chamber having an inside thereof kept in the vacuum state, a second sample table which is provided in the second vacuum chamber and holds the sample, a second solid target which is provided in the second chamber and contains the second impurity, second gas introducing means for introducing a gas for sputtering into the second chamber, second plasma generating means for exciting the gas introduced into the second chamber to generate a plasma of the gas so that the gas which is in the plasma state is caused to collide with the second target to sputter the second impurity contained in the second target, a second high frequency power source for forming a second self-bias between the plasma generated by the second plasma generating means and the second sample table to introduce the second sputtered impurity from the second target to the sample held on the second sample table, and a carrier chamber which has an inside thereof kept in the vacuum state, is communicated with the first and second vacuum chambers through shutters respectively, and includes carrier means for carrying the sample from the first sample table to the second sample table.

According to the second impurity introducing apparatus, the first and second impurities which are sputtered are introduced from the first and second targets into the surface portions of the samples held on the sample tables in the first and second vacuum chambers respectively in the same manner as in the first impurity introducing apparatus. In this case, the plasma is caused to collide with the solid target containing the impurities to be sputtered. For this reason, it is not necessary to use poisonous gases unlike the ion implanting method. Consequently, impurity introducing work can be performed with safety and a low voltage of about several tens V to 2 kV is applied to the sample table so that the impurity can be introduced with low energy. Therefore, the impurity having a high concentration can be introduced into a shallow region on the surface portion of the sample. Since the impurity can be introduced with the sample kept at a low temperature, impurity introducing processing can be performed by using an ordinary resist.

Furthermore, the carrier chamber is provided, The carrier chamber has an inside thereof kept in the vacuum state, is communicated with the first and second vacuum chambers through shutters respectively, and includes carrier means for carrying the sample from the first sample table to the second sample table. Consequently, the sample into which the first impurity is introduced in the first vacuum chamber is carried to the second vacuum chamber in the vacuum state so that the second impurity can be introduced into the second vacuum chamber. Thus, a semiconductor device into which two kinds of impurities should be introduced, for example, a CMOS transistor can be manufactured easily without lowering the characteristics.

The present invention provides an impurity introducing method for introducing an impurity into a sample such as a semiconductor substrate, comprising the steps of holding the sample on a sample table provided in a vacuum chamber which has an inside thereof kept in the vacuum state, and holding a solid target containing the impurity in the vacuum chamber, introducing a gas for sputtering into the chamber, generating a plasma of the gas introduced at the gas introducing step so that the gas which is in the plasma state is caused to collide with the target to sputter the impurity contained in the target, and introducing the sputtered impurity from the target to the sample held on the sample table by applying a high frequency power to the sample table to form a self-bias between the plasma generated at the plasma generating step and the sample table.

According to the impurity introducing method of the present invention, the impurity which is sputtered is introduced from the target into the surface portion of the sample held on the sample table in the vacuum chamber in the same manner as in the first impurity introducing apparatus. In this case, the plasma is caused to collide with the solid target containing the impurity to be sputtered. For this reason, it is not necessary to use poisonous gases unlike the ion implanting method. Consequently, impurity introducing work can be performed with safety. In addition, a low voltage of about several tens V to 2 kV is applied to the sample table so that the impurity can be introduced with low energy. Since the impurity having a high concentration can be introduced into the shallow region on the surface portion of the sample, the short channel effects can be prevented and the speed of a device can be increased in the MOSFET having a fine design rule. In addition, the speed of the bipolar transistor can be increased. Furthermore, the impurity can be introduced with the sample kept at a low temperature, for example, of 23 to 160° C. Consequently, the impurity introducing processing can be performed by using an ordinary resist.

In the impurity introducing method, it is preferable that the plasma generating step should include a step of introducing plasma waves having a frequency of 1 GHz or more into the vacuum chamber to generate a plasma of the gas. As a result, the plasma having a high density can be generated in the vacuum chamber. Consequently, the impurity having a predetermined concentration can be introduced into the surface portion of the semiconductor substrate in a short time.

In the impurity introducing method, it is preferable that the plasma generating step should include a step of raising the density of the plasma generated in the vacuum chamber by a magnetic field. As a result, the ionization efficiency of the introduced gas is enhanced so that the plasma density can be increased still more. Consequently, the impurity having a predetermined concentration can be introduced into the surface portion of the semiconductor substrate in a much shorter time.

In the impurity introducing method, it is preferable that the impurity contained in the target should be boron and nitrogen. As a result, the nitrogen atoms introduced into the gate insulating film prevents the boron introduced into the p type gate electrode from penetrating into the channel region of the n type semiconductor region at the heat treating step which will be executed later on. Consequently, the characteristics of the p type MOS transistor can be enhanced.

In the impurity introducing method, it is preferable that the target should contain boron nitride. As a result, the nitrogen atoms are introduced into the gate insulating film so that the boron introduced into the p type gate electrode can be prevented from penetrating into the channel region of the n type semiconductor region.

In the impurity introducing method, it is preferable that the gas introduced at the gas introducing step should include an argon gas and a nitrogen gas. As a result, the nitrogen atoms are introduced into the gate insulating film so that the boron introduced into the p type gate electrode can be prevented from penetrating into the channel region of the n type semiconductor region.

These and other objects, features, aspects and advantages of the present invention will become more apparent from the following detailed description of the present invention when taken in conjunction with the accompanying drawings.

### BRIEF DESCRIPTION OF THE DRAWINGS

The present invention will be detailed in conjunction with the accompanying drawings in which:

FIG. 1 is a sectional view showing an impurity introducing apparatus according to a first embodiment of the present invention;

FIG. 2 is a chart showing an impurity profile in the depth direction of a sample obtained when introducing an impurity by using the impurity introducing apparatus according to the first embodiment of the present invention and an ion implanting apparatus according to the prior art;

FIG. 3 is a plan view showing an impurity introducing apparatus according to a second embodiment of the present invention;

FIG. 4 is a sectional view showing an impurity introducing apparatus according to a third embodiment of the present invention;

FIGS. 5(a) to 5(d) are sectional views showing the steps of a method for manufacturing a semiconductor device using the impurity introducing apparatus according to the first embodiment of the present invention;

FIGS. 6(a) to 6(c) are sectional views showing the steps of a method for manufacturing a semiconductor device using the impurity introducing apparatus according to the second embodiment of the present invention; and

FIG. 7 is a chart showing the relationship between a gate voltage and a drain current obtained in the cases where nitrogen atoms are not introduced into a gate insulating film of a MOSFET and they are introduced into the gate insulating film of the MOSFET.

### DETAILED DESCRIPTION OF THE INVENTION

An impurity introducing method and apparatus and a method for manufacturing a semiconductor device according to the present invention will be described below with reference to the drawings.

(First Embodiment)

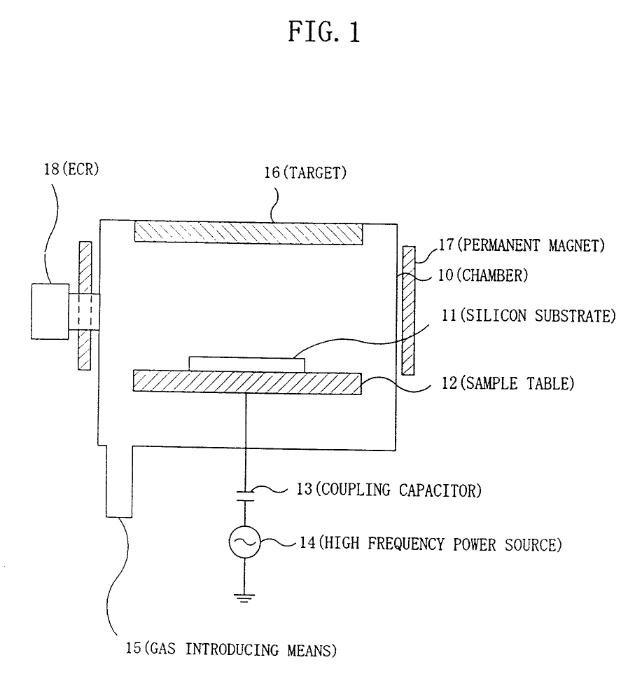

FIG. 1 shows the sectional structure of an impurity introducing apparatus according to a first embodiment of the present invention. As shown in FIG. 1, a sample table 12 for holding a sample such as a semiconductor wafer for a LSI into which an impurity is introduced, for example, a silicon substrate 11 is provided in the lower portion of a vertically cylindrical vacuum chamber 10. A high frequency power source 14 is connected to the sample table 12 through a coupling capacitor 13. The high frequency power source 14 applies a high frequency power of 800 kHz to 100 MHz, for example, 13.56 MHz. The high frequency power source 14 has a self-bias of 500 V, for example. Gas introducing means 15 for introducing a sputtering gas such as an argon gas is provided on the bottom of the vacuum chamber 10. Besides the argon gas, a helium gas, a nitrogen gas or the like can be used as the sputtering gas.

For example, three to four board-shaped permanent magnets which act as magnetic field generating means for generating a magnetic field in the vacuum chamber 10 are arranged at proper intervals on the outer periphery of the vacuum chamber 10. An ECR (Electron Cyclotron Resonance) 18 is provided on the outside of the vacuum chamber 10 so as to extend from the permanent magnets 17 and to be connected to the vacuum chamber 10. The ECR 18 acts as plasma generating means for introducing microwaves having a frequency, for example, of 2.45 GHz into the vacuum chamber 10. A solenoid coil may be provided as the magnetic field generating means in place of the board-shaped permanent magnet 17. An ICP, a helicon, a magnetron, a two-cycle, a triode, a LEP or the like can suitably be used as the plasma generating means in place of the ECR 18. An apparatus for introducing plasma waves having a frequency of 1 GHz or more is preferable for the following reasons.

As the characteristics of the first embodiment, a solid target 16 which contains an impurity (for example, boron) to be introduced is provided in the upper portion of the vacuum chamber 10. The impurity contained in the target 16 is an element which is usually used for doping semiconductors, for example, arsenic, phosphorus, indium, antimony, nitrogen, aluminum, silicon and the like in addition to boron.

A method for introducing the impurity into the silicon substrate 11 by using the impurity introducing apparatus according to the first embodiment will be described below.

First of all, a gas for sputtering (for example, argon) is introduced from the gas introducing means 15 into the vacuum chamber 10 and microwaves are introduced from the ECR 18 into the vacuum chamber 10. Consequently, the gas for sputtering introduced into the vacuum chamber 10 is ionized by the microwaves and brought into the plasma state. Argon atoms which are in the plasma state are accelerated by a plasma potential formed in the vacuum chamber 10 and collide with the surface of the target 16 containing the impurity. By the collision, the impurity is sputtered from the target 16. The impurity which is sputtered from the target 16 receives energy from the argon atoms which are approaching the sample table 12 at a self-bias generated between the sample table 12 and the argon atoms in the plasma state with a high frequency power applied to the sample table 12, and are implanted into the surface portion of the silicon substrate 11 which is provided opposite to the target 16.

In a sputtering apparatus according to the prior art, a material forming a target is a metal. For this reason, a parallel plate type plasma generating apparatus which has no plasma generating means such as an ECR also generates a plasma. However, in the case where the target 16 containing boron is used as in the first embodiment, an electric field which is generated is emitted because the boron has high insulating properties. Therefore, it is hard to generate the plasma. In the first embodiment, the ECR 18 is provided to introduce the microwaves having a frequency of 1 GHz or more into the vacuum chamber 10. When the microwaves having a frequency of 1 GHz or more are introduced into the vacuum chamber 10, a plasma having a density which is about 1000 times as much as that of the parallel plate type plasma generating device is generated. Consequently, the impurity such as boron can be implanted into the surface portion of the silicon substrate 11 in a short time. For this reason, the temperature of the silicon substrate 11 does not exceed 160° C. so that a resist pattern formed on the silicon substrate 11 can be prevented from burning.

It is also considered that the frequency of the high-frequency power to be applied to the sample table 12 is set to 1 GHz or more. In this case, however, the effects of the self-bias generated between the sample table 12 and the plasma are decreased. Consequently, it is hard to implant the impurity into the surface portion of the silicon substrate 11 and to dispose electromagnetic wave shielding means for shielding microwaves having a frequency of 1 GHz or more in the vacuum chamber 10. As a result, the problems of safety also arise.

In the first embodiment, the permanent magnet 17 for generating a magnetic field is provided in the vacuum chamber 10. Consequently, the ionization efficiency of the argon gas is enhanced by the cooperation of the microwaves introduced by the ECR 18 and the magnetic field generated by the permanent magnet 17. For this reason, the impurity such as boron can be implanted into the surface portion of the silicon substrate 11 in a much shorter time. Thus, a rise in temperature of the silicon substrate 11 can be controlled still more.

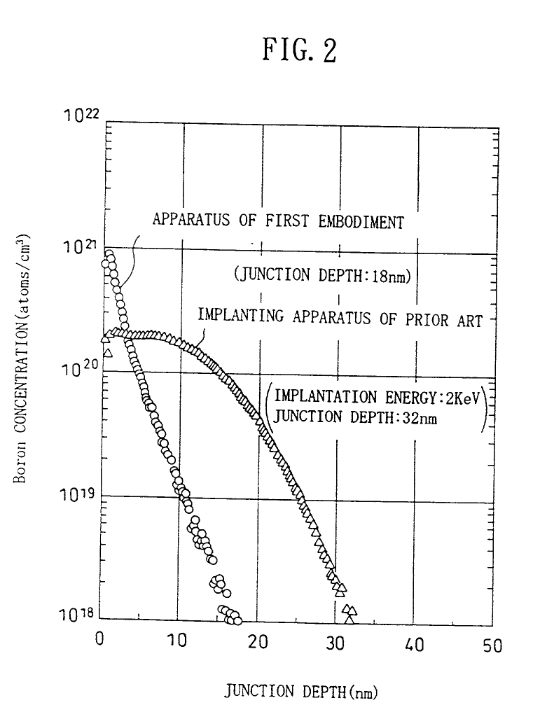

FIG. 2 shows a SIMS profile of the silicon substrate into which the impurity is introduced by the impurity introducing method according to the first embodiment and of the silicon substrate into which the impurity is introduced by an ion implanting apparatus according to the prior art.

As is apparent from FIG. 2, the concentration of the impurity introduced into the surface portion of the silicon substrate is 1×10²¹ (/cm³) and a junction depth for an impurity concentration of 1×10¹⁸ (/cm³) is 18 nm in the impurity introducing method according to the first embodiment. On the other hand, the concentration of the impurity introduced into the surface portion of the silicon substrate is 3×10²⁰ (/cm³) and a junction depth for an impurity concentration of 1×10¹⁸ (/cm³) is 32 nm in the ion implanting method according to the prior art (an acceleration voltage of 2 KeV).

As described above, the gas which contains the impurity elements to be introduced into the silicon substrate is supplied into the vacuum chamber, and the impurity gas is excited and introduced into the silicon substrate by the ion implanting method according to the prior art. According to the first embodiment in which the impurity to be introduced into the silicon substrate 11 is contained in the solid target 16 and the silicon substrate 11 is doped with the impurity by sputtering, plasma doping is performed with low energy generated by a difference in potential of the plasma and the silicon substrate 11 (about several tens V to 2 kV) so that the impurity is introduced into the surface portion of the silicon substrate 11. Thus, the impurity can be introduced with much lower energy than a difference in potential which is used for the ion implanting method according to the prior art (ordinarily, about 30 kV). Therefore, an impurity layer which is shallow and has a high concentration can be formed on the surface portion of the silicon substrate 11 in such a manner that the impurity concentration is high in the vicinity of the surface. Consequently, it is easy to obtain a transistor element having small short channel effects and great driving force in a device having a fine design rule.

According to the first embodiment, the solid target 16 is used as the impurity with which the silicon substrate 11 is doped. Unlike the prior art, gaseous impurities are not handled. Consequently, the impurity introducing apparatus has great safety and can be simplified.

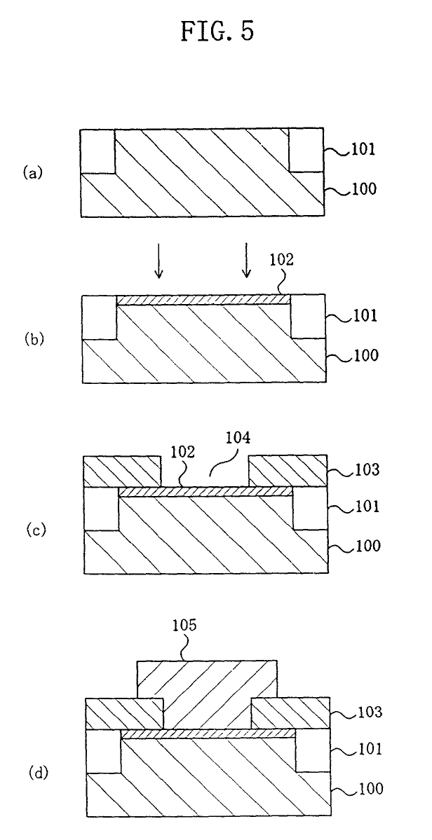

A method for manufacturing a semiconductor device by using the impurity introducing apparatus according to the first embodiment will be described below with reference to FIG. 5.

As shown in FIG. 5(a), an element isolating region 101 is formed on an n type semiconductor substrate 100. With the semiconductor substrate 100 kept at a temperature of 160° C. or less in the vacuum chamber 10 having a vacuum of several to several tens mtorr, an argon gas is introduced from the gas introducing means 15, microwaves having a frequency of 1 GHz or more are introduced from the ECR 18 and a high frequency power is applied from the high frequency power source 14 to the sample table 12. Thus, the argon which is brought into the plasma state in the vacuum chamber 10 is caused to collide with the target 16 containing an impurity, for example, boron at a self-bias of 500 V or less for about several sec. to 10 mins. Consequently, impurity atoms are discharged from the target 16. The impurity atoms discharged from the target 16, for example, boron atoms are introduced into the surface portion of the semiconductor substrate 100.

Then, the semiconductor substrate 100 is heat-treated to diffuse the impurity so that a high concentration diffusion layer 102 having a surface concentration of 1×10²¹ (/cm³) or more and a depth of 50 nm or less is formed on the surface portion of the semiconductor substrate 100 as shown in FIG. 5(b).

Subsequently, a layer insulating film 103 is deposited over the semiconductor substrate 100. Thereafter, photolithography and etching are performed on the layer insulating film 103. Thus, a contact hole 104 is formed on the layer insulating film 103 as shown in FIG. 5(c).

As shown in FIG. 5(d), an electrode 105 is formed on the layer insulating film 103 including the contact hole 104 so that a diode is obtained.

By using the impurity introducing apparatus according to the first embodiment, it is also possible to manufacture n or p channel MOS transistors whose drawings and detailed description will be omitted.

(Second Embodiment)

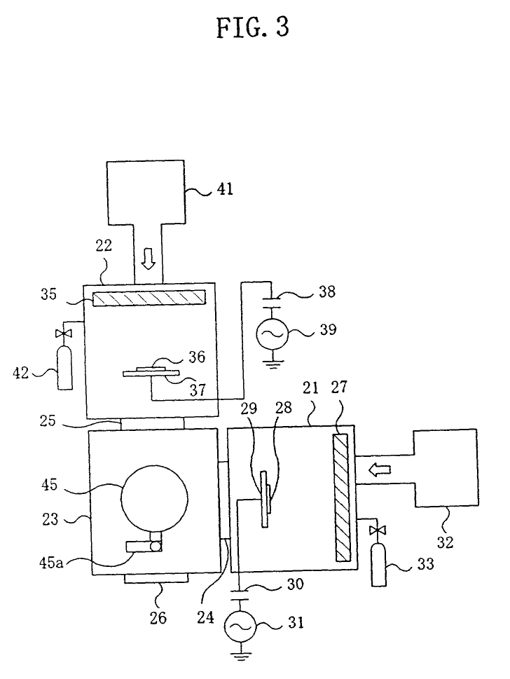

FIG. 3 shows the planar structure of an impurity introducing apparatus according to a second embodiment of the present invention. As shown in FIG. 3, a first vacuum chamber 21 is communicated with a second vacuum chamber 22 through a carrier chamber 23 which is kept in the vacuum state. A first shutter 24 is provided between the first vacuum chamber 21 and the carrier chamber 23. A second shutter 25 is provided between the second vacuum chamber 22 and the carrier chamber 23. A third shutter 26 is provided on the carrier chamber 23 to carry a sample therein and therefrom.

In the same manner as in the first embodiment, the first vacuum chamber 21 is provided with a first target 27 which is solid and contains a p-type impurity comprising boron and a first sample table 29 for holding a semiconductor substrate 28. A first high frequency power source 31 for applying a high frequency power having a frequency of 800 kHz to 100 MHz, for example, is connected to the first sample table 29 through a first coupling capacitor 30. In addition, the first vacuum chamber 21 is provided with a microwave generating device 32 for introducing plasma waves and a first gas supply device 33 for introducing a sputtering gas such as argon.

The second vacuum chamber 22 is also provided with a second target 35 which is solid and contains an n type impurity comprising arsenic or phosphorus and a second sample table 37 for holding a semiconductor substrate 36. A second high frequency power source 39 for applying a high frequency power having a frequency of 800 kHz to 100 MHz, for example, is connected to the second sample table 37 through a second coupling capacitor 38. In addition, the second vacuum chamber 22 is provided with a second microwave generating device 41 for introducing plasma waves and a second gas supply device 42 for introducing a sputtering gas such as argon.

The carrier chamber 23 is provided with a carrier device 45 having an arm 45a. The semiconductor substrates 28 and 36 are carried in or from the first and second chambers 21 and 22 by the carrier device 45. Consequently, the semiconductor substrate into which the p type impurity has been introduced in the first chamber 21 is carried into the second chamber 22 in the vacuum state, and an n type impurity can be introduced into the semiconductor substrate in the second chamber 22. Since a method for introducing the impurity into the semiconductor substrate by using the impurity introducing apparatus according to the second embodiment is the same as in the first embodiment, its description will be omitted.

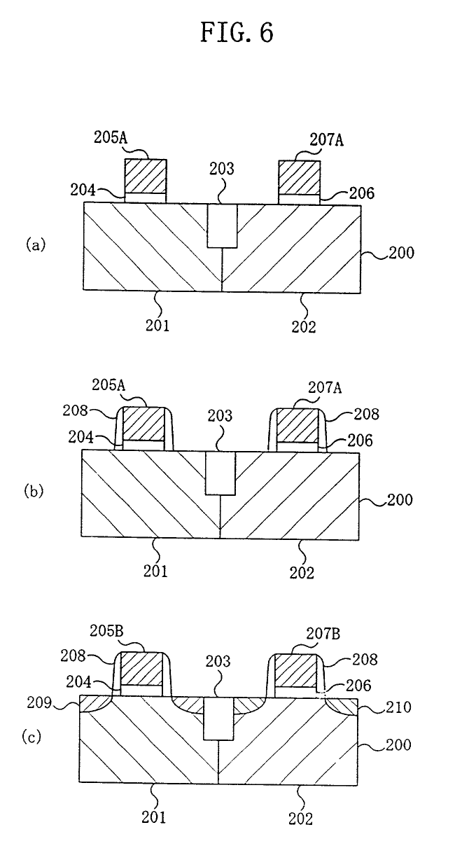

A method for manufacturing a semiconductor device by using the impurity introducing apparatus according to the second embodiment will be described below with reference to FIG. 6.

As shown in FIG. 6(a), a p type semiconductor region 201 which is an n channel MOS transistor formation region, an n type semiconductor region 202 which is a p channel MOS transistor formation region, and an element isolating layer 203 for isolating the p type semiconductor region 201 from the n type semiconductor region 202 are formed on a p type semiconductor substrate 200 made of silicon. Then, a first gate insulating film 204 made of a silicon oxide film having a thickness of 4 to 10 nm and a first gate electrode 205A made of a polysilicon film having a thickness of 100 to 300 nm are sequentially formed on the p type semiconductor region 201. A second gate insulating film 206 made of a silicon oxide film having a thickness of 4 to 10 nm and a second gate electrode 207A made of a polysilicon film having a thickness of 100 to 300 nm are sequentially formed on the n type semiconductor region 202.

Subsequently, a silicon oxide film having a thickness of 100 to 200 nm is deposited over the semiconductor substrate 200 by a CVD method. Then, the silicon oxide film is etched back by anisotropic etching. Thus, a side wall 208 is formed on the sides of the first and second gate electrodes 205A and 207A as shown in FIG. 6(b).

After the semiconductor substrate 200 is carried in the second vacuum chamber 22, argon which is in the plasma state is caused to collide with the second target 35 containing an n type impurity, for example, As (arsenic) at a self-bias of 5 keV or less for about several secs. to 10 mins. with the second vacuum chamber 22 kept at a vacuum of several to several tens mtorr and the semiconductor substrate 200 kept at a temperature of 160° C. or less. Thus, the n type impurity which is sputtered, for example, As is introduced from the second target 35 into the p type semiconductor region 201 and the first gate electrode 205A by using the side wall 208 as a mask. As shown in FIG. 6(b), thus, an n type source-drain region 209 is formed in the p type semiconductor region 201 and the first gate electrode 205A is changed to an n type gate electrode 205B having a low resistance. Consequently, an n type MOS transistor is formed. Then, the semiconductor substrate 200 is transferred from the second vacuum chamber 22 to the first vacuum chamber 21 by the carrier device 45. Thereafter, argon which is in the plasma state is caused to collide with the first target 27 containing a p type impurity, for example, B (boron) at a self-bias of 500 V or less for about several secs. to 10 mins. with the first vacuum chamber 21 kept at a vacuum of several to several tens mtorr and the semiconductor substrate 200 kept at a temperature of 160° C. or less. Thus, the p type impurity which is sputtered, for example, B is introduced from the first target 27 into the n type semiconductor region 202 and the second gate electrode 207A by using the side wall 208 as a mask. Thus, a p type source-drain region 210 is formed in the n type semiconductor region 202 and the second gate electrode 207A is changed to a p type gate electrode 207B having a low resistance. Consequently, a p type MOS transistor is formed.

Subsequently, the semiconductor substrate 200 is heat-treated at a temperature of 900 to 1050° C. for 1 to 60 secs. Consequently, the impurity ions which have been introduced into the n and p type source-drain regions 209 and 210 are activated. Thus, the n and p type source drain regions 209 and 210 are changed to high concentration impurity diffusion layers having a surface impurity concentration of 1×10²¹ (/cm³) or more and a depth of 50 nm or less. Then, a metallic wiring layer having some layers is formed on the semiconductor substrate 200 through a layer insulating film so that a semiconductor device having a CMOS transistor can be obtained, which is not shown.

(Third Embodiment)

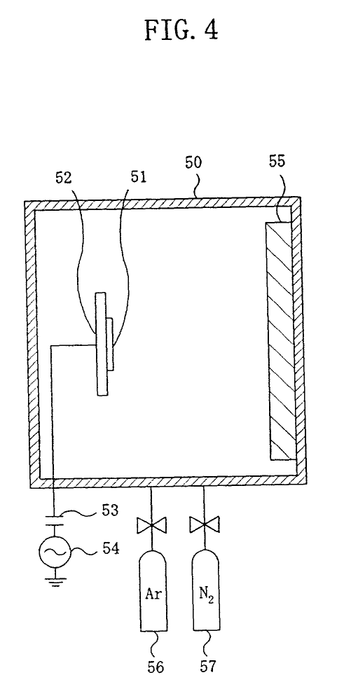

FIG. 4 shows the sectional structure of an impurity introducing apparatus according to a third embodiment of the present invention. As shown in FIG. 4, a sample table 52 which holds a silicon substrate 51 is provided in a vacuum chamber 50, for example. A high frequency power source 54 for applying a high frequency power having a frequency of 800 kHz to 100 MHz is connected to the sample table 52 through a coupling capacitor 53. For example, the high frequency power source 54 has a self-bias of 500 V. A solid target 55 containing an impurity (for example, boron) which should be introduced is provided in the vacuum chamber 50.

As the characteristics of the third embodiment, the vacuum chamber 50 is provided with first gas introducing means 56 for introducing a sputtering gas such as argon and second gas introducing means 57 for introducing an inert gas such as nitrogen.

If plasma generating means for supplying plasma waves such as an ECR, an ICP, a helicon, a magnetron, a two-cycle, a triode, a LEP or the like (not shown) is provided in the impurity introducing apparatus according to the third embodiment, a plasma having a high density can be generated for the same reasons as in the first embodiment.

A method for introducing the impurity into the silicon substrate 51 by using the impurity introducing apparatus according to the third embodiment will be described below.

When an argon gas is introduced from the first gas introducing means 56 and a nitrogen gas is introduced from the second gas introducing means 57 into the vacuum chamber 50, the argon gas and the nitrogen gas are ionized by the high frequency power applied by the high frequency power source 54 and are brought into the plasma state. Argon and nitrogen atoms which are in the plasma state are accelerated by a plasma potential in the vacuum chamber 50 and collide with the target 55. The impurity, for example, boron sputtered from the target 55. The impurity which is sputtered from the target 55 and the nitrogen atoms which are in the plasma state are introduced into the surface portion of the silicon substrate 51 at a self-bias generated between the plasma and the silicon substrate 51.

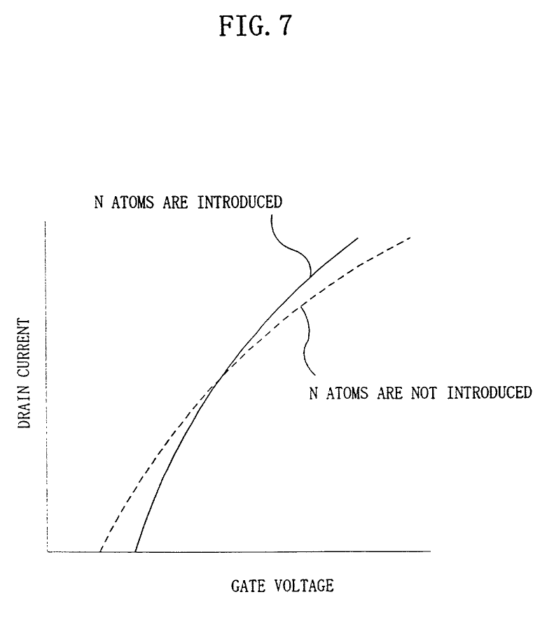

In the case where the impurity introducing method according to the third embodiment is applied to the step of forming a p type MOS transistor in the method for manufacturing a semiconductor device which has been described with reference to FIG. 6, boron which is sputtered from the target 55 is introduced into the n type semiconductor region 202 and the second gate electrode 207A so that the p type source-drain region 210 and the p-type gate electrode 207B are formed and the nitrogen atoms are introduced into the second insulating film 206. For this reason, the nitrogen atoms introduced into the second insulating film 206 prevent the boron introduced into the p-type gate electrode 207B from penetrating into the channel region of the n type semiconductor region 202 at the heat-treating step which will be executed later on. Consequently, the characteristics of the p type MOS transistor can be enhanced. FIG. 7 shows the relationship between a gate voltage and a drain current obtained in the cases where the nitrogen atoms are not introduced and are introduced. As is apparent from FIG. 7, the nitrogen atoms are introduced so that the drain current is increased. Consequently, the characteristics of the transistor can be enhanced.

Also in the case where the target 55 which contains nitrogen or boron nitride besides the impurity that should be introduced into the semiconductor substrate 51 is provided in the vacuum chamber 50 in place of the first gas introducing means 56 for introducing an argon gas and the second gas introducing means 57 for introducing a nitrogen gas, the same effects as in the third embodiment can be obtained.

Although the present invention has fully been described by way of example with reference to the accompanying drawings, it is to be understood that various changes and modifications will be apparent to those skilled in the art. Therefore, unless otherwise such changes and modifications depart from the scope of the invention, they should be construed as being included therein.

We/I claim:

1. An impurity introducing apparatus for introducing an impurity into a sample such as a semiconductor substrate or the like, comprising:
a vacuum chamber having an inside thereof kept in the vacuum state;
a sample table which is provided in said vacuum chamber and holds said sample;
a solid target which is provided in said chamber and contains said impurity;
gas introducing means for introducing a gas for sputtering into said chamber;
plasma generating means for exciting said gas introduced into said chamber to generate a plasma of said gas so that the gas which is in the plasma state is caused to collide with said target to sputter said impurity contained in said target; and
a high frequency power source for forming a self-bias between said plasma generated by said plasma generating means and said sample table to introduce said sputtered impurity from said target into the surface portion of said sample held on said sample table.

2. The impurity introducing apparatus as defined in claim 1, wherein said plasma generating means is provided on the outside of said vacuum chamber and introduces plasma waves having a frequency of 1 GHz or more into said vacuum chamber.

3. The impurity introducing apparatus as defined in claim 2, further comprising magnetic field generating means for generating a magnetic field which raises the density of said plasma generated in said vacuum chamber.

4. The impurity introducing apparatus as defined in claim 1, wherein said target contains boron and nitrogen as said impurity.

5. The impurity introducing apparatus as defined in claim 1, wherein said target contains boron nitride.

6. The impurity introducing apparatus as defined in claim 1, wherein said gas introduced by said gas introducing means includes an argon gas and a nitrogen gas.

7. An impurity introducing apparatus for introducing first and second impurities into a sample such as a semiconductor substrate, comprising:
a first vacuum chamber having an inside thereof kept in the vacuum state;
a first sample table which is provided in said first vacuum chamber and holds said sample;
a first solid target which is provided in said first chamber and contains said first impurity;
first gas introducing means for introducing a gas for sputtering into said first chamber;
first plasma generating means for exciting said gas introduced into said first chamber to generate a plasma of said gas so that the gas which is in the plasma state is caused to collide with said first target to sputter said first impurity contained in said first target;
a first high frequency power source for forming a first self-bias between said plasma generated by said first plasma generating means and said first sample table to introduce said first sputtered impurity from said first target into said sample held on said first sample table;
a second vacuum chamber having an inside thereof kept in the vacuum state;
a second sample table which is provided in said second vacuum chamber and holds said sample;
a second solid target which is provided in said second chamber and contains said second impurity;
second gas introducing means for introducing a gas for sputtering into said second chamber;
second plasma generating means for exciting said gas introduced into said second chamber to generate a plasma of said gas so that said gas which is in the plasma state is caused to collide with said second target to sputter said second impurity contained in said second target;
a second high frequency power source for forming a second self-bias between said plasma generated by said second plasma generating means and said second sample table to introduce said second sputtered impurity from said second target to said sample held on said second sample table; and
a carrier chamber which has an inside thereof kept in the vacuum state, is communicated with said first and second vacuum chambers through shutters respectively, and includes carrier means for carrying said sample from said first sample table to said second sample table.

8. An impurity introducing method for introducing an impurity into a sample such as a semiconductor substrate, comprising the steps of:
holding said sample on a sample table provided in a vacuum chamber which has an inside thereof kept in the vacuum state, and holding a solid target containing said impurity in said vacuum chamber;
introducing a gas for sputtering into said chamber;
generating a plasma of said gas introduced at said gas introducing step so that the gas which is in the plasma state is caused to collide with said target to sputter said impurity contained in said target; and
introducing the sputtered impurity from said target to said sample held on said sample table by applying a high frequency power to said sample table to form a self-bias between said plasma generated at said plasma generating step and said sample table.

9. The impurity introducing method as defined in claim 8, wherein said plasma generating step includes a step of introducing plasma waves having a frequency of 1 GHz or more into said vacuum chamber to generate a plasma of said gas.

10. The impurity introducing method as defined in claim 9, wherein said plasma generating step includes a step of raising the density of said plasma generated in said vacuum chamber by a magnetic field.

11. The impurity introducing method as defined in claim 8, wherein said impurity contained in said target is boron and nitrogen.

12. The impurity introducing method as defined in claim 8, wherein said target contains boron nitride.

13. The impurity introducing method as defined in claim 8, wherein said gas introduced at said gas introducing step includes an argon gas and a nitrogen gas.
